(19) United States
(12) Patent Application Publication
(10) Pub. No.: US 2010/0151129 A1
(43) Pub. Date: Jun. 17, 2010

(54) METHOD AND ARRANGEMENT FOR PROVIDING CHALCOGENS

(75) Inventors: Dieter Schmid, Reutlingen (DE); Reinhard Lenz, Blaubeuren (DE); Robert Michael Hartung, Blaubeuren (DE)

Correspondence Address: HESLIN ROTHENBERG FARLEY & MESITI PC, 5 COLUMBIA CIRCLE, ALBANY, NY, 12203, US

(73) Assignee: CENTROTHERM PHOTOVOLTAICS AG, Blaubeuren (DE)

(21) Appl. No.: 12/529,872

(22) PCT Filed: Sep. 11, 2008
(86) PCT No.: PCT/EP2008/062061

§ 371 Date: Feb. 3, 2010

(30) Foreign Application Priority Data
Sep. 11, 2007 (DE) 10 2007 043 051.7
Oct. 1, 2007 (DE) 10 2007 047 098.5
Oct. 1, 2007 (DE) 10 2007 047 099.3
Oct. 8, 2007 (DE) 10 2007 048 204.5

(51) Int. Cl. C23C 14/06; C23C 14/56

(52) U.S. Cl. 427/255.23; 118/715; 118/724

(57) ABSTRACT

A method and an arrangement for providing chalcogens as thin layers on substrates, in particular on planar substrates prepared with precursor layers and composed of any desired materials, preferably on substrates composed of float glass is achieved by forming an inlet- and outlet-side gas curtain for an oxygen-tight closure of a transport channel in a vapour deposition head, introducing an inert gas into the transport channel for displacing atmospheric oxygen, introducing one or more substrates to be coated, the substrates being temperature-regulated to a predetermined temperature, into the transport channel, introducing a chalcogen vapour/carrier gas mixture from a source into the transport channel at the vapour deposition head above the substrates and forming a selenium layer on the substrates by PVD at a predetermined pressure, and removing the substrates after a predetermined process time has elapsed.

The invention relates to a method and an arrangement for providing chalcogens in the form of thin layers on substrates, in particular on planar substrates prepared with precursor layers and composed of any desired materials, preferably on substrates composed of float glass.

The present invention concerns a novel source (installation component) for the thermal evaporation of selenium, sulphur, tellurium and compounds thereof among one another or with other substances or mixtures thereof, which are generally also referred to as chalcogens, in order then to deposit them on the large-area substrates, which have previously been provided with molybdenum and thereon with metallic precursor layers composed of copper/gallium or indium. These metallic layers are subsequently converted with the aid of the chalcogens, in further processes, into compound semiconductor layers for producing solar modules. The substrates can have the customary dimensions of e.g. 1.25×1.1 m for photovoltaic solar modules.

The chalcogens are required as process substances for converting the metallic precursor layers into the compound semiconductor layer. Typical conversion temperatures are 500-600° C. In this case, the conversion temperature is so high that the chalcogens present in the solid state of matter at room temperature around 20° C. evaporate within the process installation. In this case, the chalcogens are evaporated again from the substrates, or additionally fed to a process chamber. The source for producing the chalcogen layer on the metalized substrates is operated at atmospheric pressure, that is to say at approximately 1000 hPa.

Methods are known which, for the coating of the substrates prepared in advance with precursor layers with chalcogens, either utilize high vacuum or else proceed under atmospheric conditions but then use hydrogen-containing gases, as revealed by EP 0 318 315 A2. A method which utilizes atmospheric pressure (around 1000 hPa) has not been afforded heretofore either in research or in industrial application for coating with said chalcogens. The coating with said chalcogens is effected in the high-vacuum method at pressures of between 10⁻⁶ hPa and 10⁻³ hPa, the selenium or the sulphur in this case being thermally evaporated in the high vacuum.

The disadvantage of high-vacuum processes is the expensive equipment, comprising vacuum chambers, valves and vacuum pumps. Long pump times are the rule here, and likewise lock introduction and discharge times of the substrates into the vacuum chambers. Vacuum is generally used in order to avoid the element oxygen during coating with selenium, sulphur or mixtures of selenium and sulphur. In the presence of oxygen, the selenium reacts to form a toxic compound (selenium oxide) which is disruptive for the further processes, such as e.g. the conversion of the metal layers with the aid of the chalcogens to form a semiconducting layer, a so-called chalcopyrite layer, or impairs the function of the semiconductor layer and drastically reduces the efficiency.

High-vacuum processes generally lead to high costs in industrial mass production. Pump and lock times lead to increased cycle times and thus always to low productivity besides long process times.

One solution would be, on the one hand, to use many machines simultaneously, but this would require high capital expenditure, or else to accelerate the processes.

The object to be achieved consists in providing a very fast and cost-effective coating method for chalcogens, in particular for applying thin layers of the chalcogens within the range of 100 nm to 10 μm, or mixtures of these materials, on planar substrates and also an apparatus suitable for carrying out the method.

In the case of a method of the type mentioned in the introduction, the object on which the invention is based is achieved by forming an inlet- and outlet-side gas curtain for the oxygen-tight closure of a transport channel in a vapour deposition head, introducing an inert gas into the transport channel for displacing the atmospheric oxygen, introducing one or more substrates to be coated, said substrates being temperature-regulated to a predetermined temperature, into the transport channel of the process chamber, introducing a chalcogen vapour/carrier gas mixture from a source into the transport channel at the vapour deposition head above the substrates and forming a selenium layer on the substrates by means of PVD at a predetermined pressure, and removing the substrates after a predetermined process time has elapsed.

Preferably, approximately an atmospheric pressure with deviations of +/− a few pascals is set in the process chamber.

In order to ensure a uniform coating with the chalcogens, the substrates are moved relative to a vapour deposition head during the coating, the substrates being moved at a constant speed.

It is furthermore advantageous if the substrates are temperature-regulated to a temperature of below 200° C. prior to being transported into the transport channel of the process chamber, e.g. to a temperature of 20° C. to 50° C. or else room temperature.

In a development of the invention, the coating process is formed with exclusion of oxygen by means of a gas curtain formed on the inlet and outlet sides of the transport channel in the process chamber, said gas curtain being composed of an inert gas, e.g. of a noble gas such as argon.

Finally, the chalcogen vapour/carrier gas mixture is conducted directly onto the surface of the substrates.

The object on which the invention is based is furthermore achieved by means of an apparatus for carrying out the method in that a process chamber is provided with a transport channel which is assigned a transport device for flat substrates, in that the transport channel is provided with an oxygen-tight gas curtain composed of inert gas or a noble gas on the inlet and outlet sides, in that the transport channel can be filled with a carrier gas in the process chamber between the gas curtains, and in that a vapour deposition head is arranged directly above the substrates above the transport channel, said vapour deposition head being connected to a feed device for a chalcogen vapour/carrier gas mixture.

In a first configuration of the invention, the vapour deposition head is provided with a slot—which runs transversely with respect to the transport direction of the substrate and is directed at the latter—for feeding the chalcogen vapour/carrier gas mixture.

The vapour deposition head between an evaporation chamber and the slot is provided with a plurality of constrictions followed by expansion zones one behind another over the entire width of said slot, such that the chalcogen vapour/carrier gas mixture is multiply compressed and expanded on its way to the slot, and thus distributed uniformly over the width of the slot.

In a special configuration of the invention, the vapour deposition head is configured like a spray head and provided with a multiplicity of outflow openings.

The vapour deposition head and the evaporation source including the associated connecting elements can be heated by means of a suitable heating system, e.g. an electrical heating system.

In a development of the invention, all components with which the chalcogen vapour or the chalcogen vapour/carrier gas mixture can make contact are composed of a material resistant to this mixture, such as graphite.

Furthermore, the pressure in the process chamber can be set to atmospheric pressure.

The substrates can be temperature-regulated to a temperature of between −50° C. and +100° C., or to room temperature, on the transport device.

It is also possible to temporarily increase the process pressure during the coating with the chalcogens without bringing the substrates into contact with oxygen in the process.

This is possible by excluding oxygen with the aid of so-called nitrogen curtains. Heretofore, however, only the removal of oxygen by vacuum pumps was utilised for the present problem.

The entry of oxygen must absolutely be avoided during the coating because otherwise oxygen is also incorporated into the coating with the chalcogens. Oxygen reacts chemically with selenium and sulphur, in which case primarily the compounds between selenium and oxygen would be harmful for the subsequent reactions of the system to form chalcopyrite semiconductors.

Advantages of the present method include a significantly faster coating, shorter cycle times in the industrial process and a more cost-effective fabrication since lower costs in terms of capital expenditure arise owing to fewer installations.

The present invention concerns a novel process (method) for any desired substrates in which thin chalcogen layers are applied to large-area substrates, e.g. composed of float glass, under atmospheric conditions or at pressures between fine vacuum and atmospheric pressure.

A special feature of the present invention is that rather than working under high vacuum, atmospheric ambient pressure is employed, whereby the installation technology is significantly simplified. Particularly when working under atmospheric conditions, no vacuum pumps or vacuum valves at all are required.

For the further process steps it is necessary for the coating with the chalcogens to be effected with absolute exclusion of oxygen. This exclusion of oxygen is usually achieved by the use of vacuum methods in the prior art.

A much simpler method is the use of continuous methods that work with so-called nitrogen or inert gas curtains. In this case, the entry of oxygen into the process installation is avoided or excluded by virtue of the fact that the substrates pass through a gas curtain in the form of a strong flow of nitrogen or inert gas (e.g. noble gases such as argon) before they pass into the actual coating zone. After passing through the gas curtain, the substrates are situated in a space that is practically free of oxygen. In this case, free of oxygen means a residual oxygen content of less than 5 ppm oxygen in the residual gas. Under these conditions it is possible to produce high-quality coatings with chalcogens.

The invention will be explained in more detail below on the basis of an exemplary embodiment. In the associated drawings:

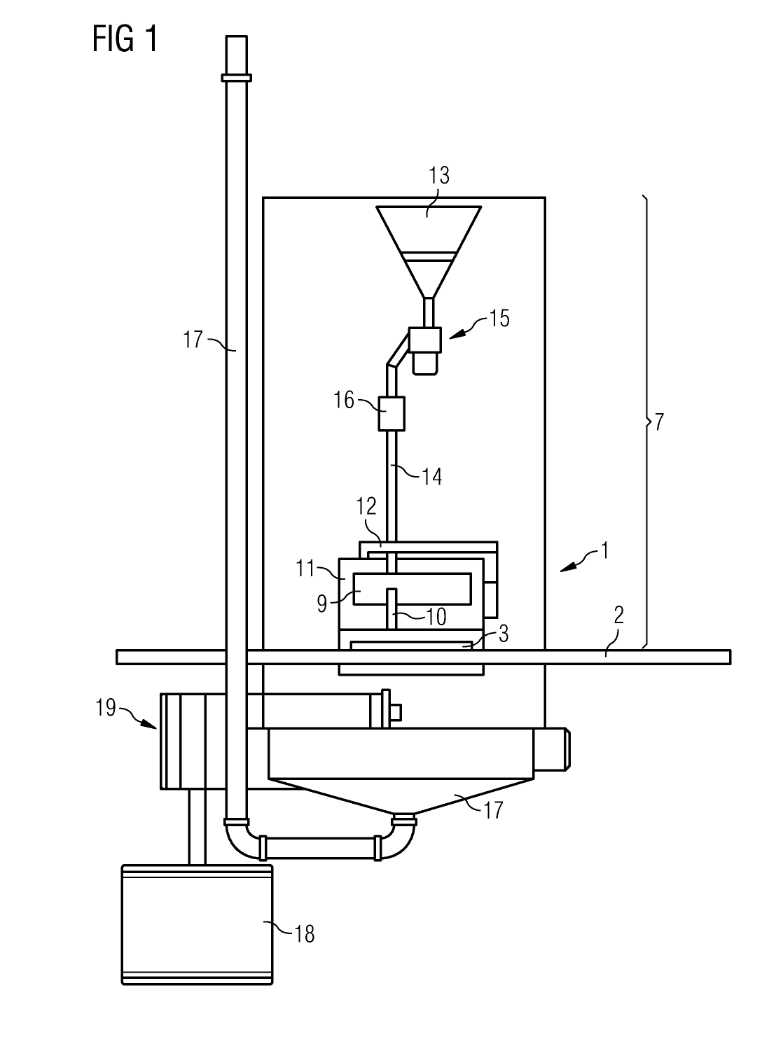

FIG. 1 shows an overview illustration of an apparatus for carrying out a coating method with chalcogens, in particular for applying thin layers of these materials on large-area substrates;

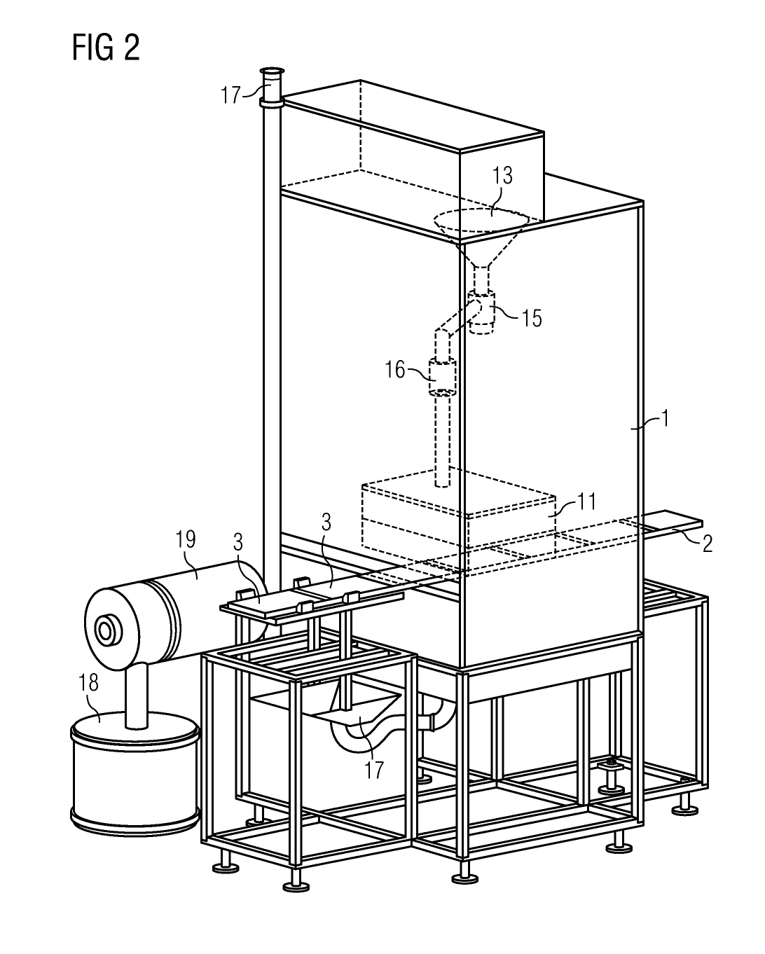

FIG. 2 shows a perspective side view of the apparatus according to FIG. 1; and

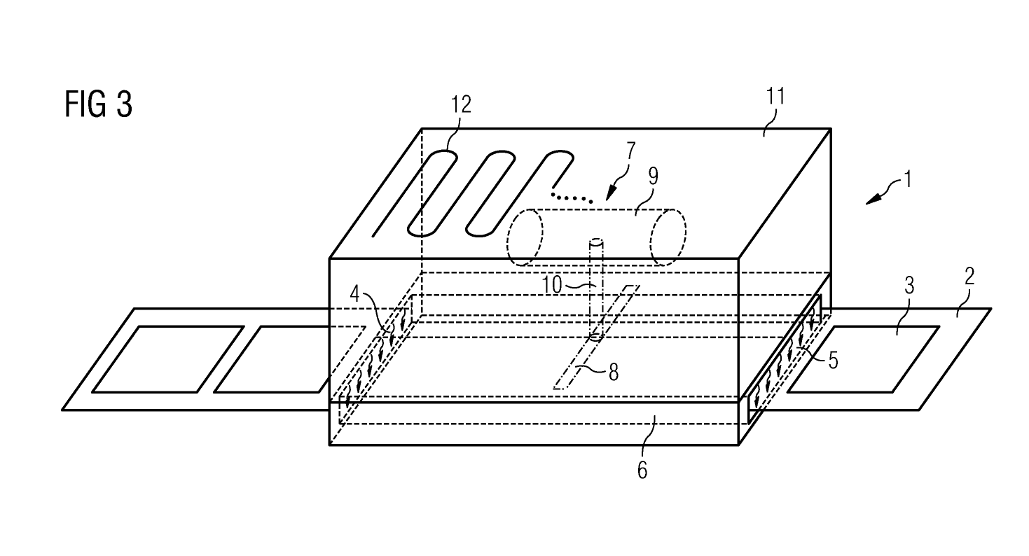

FIG. 3 shows a schematic illustration of the vapour deposition head with associated transport device for transporting large-area substrates through the transport channel in the vapour deposition head.

FIG. 1 shows a process chamber 1 suitable for continuous operation and having a transport device 2 for supplying and for transporting away large-area substrates 3 to further processing stations, such as e.g. a heat treatment furnace (not illustrated). The process chamber 1, which is equipped with an internal transport channel 6 in a vapour deposition head 11, comprises a double-walled high-grade steel chamber. By contrast, owing to the small thermal expansion, the vapour deposition head 11 with transport channels 6 leading through it is preferably composed of graphite, which does not react with selenium and has a good thermal stability with optimum temperature distribution.

The transport channel 6 of the process chamber 1 is equipped with an inlet-side and an outlet-side lock 4, 5 in each case comprising a multistage gas curtain composed of nitrogen or an inert gas in the transport channel 6 of the substrates 3 (FIG. 3), such that when the interior of the vapour deposition head 11 and of the transport channel 6 is filled with a carrier gas, the atmospheric oxygen otherwise situated there is displaced (FIG. 3). Argon, too, can be used as inert gas. The multistage gas curtain of each lock 4, 5 comprises two nitrogen curtains situated alongside one another, with gas flows directed oppositely to one another in each case from the top and bottom, whereby a small excess pressure is produced centrally in the lock region, and also an extraction system at the top and bottom between the two nitrogen curtains.

For this purpose, gas outflow openings and extraction nozzles (not illustrated) are situated at the top in the ceiling of the transport channel 6 and at the bottom on the inlet and outlet sides.

It should be pointed out that a transport channel 6 that is open on one side and provided with a gas curtain there can also be equipped and operated in a vapour deposition head 11 according to the invention, although in that case not in continuous operation but rather in batch operation.

Situated in the oxygen-free region between the two locks 4,5 is a feed device for chalcogens 7, e.g. selenium, by means of a carrier gas in the form of a slot 8 in the ceiling of the transport channel 6 of the process chamber 1. Said slot 8 is connected to a chamber 9 in a vapour deposition head 11 for liquid and vaporous selenium above the transport channel 6 through a channel 10 and is provided with a heating device 12 (indicated schematically in FIG. 3). The generation of selenium vapour is greatly temperature-dependent, the vapour generation increasing greatly between 350° C. and 550° C., such that the required heating system should be equipped with a temperature regulating means.

The chamber 9 is a simple horizontal hole through the vapour deposition head 11 and is closed off at both ends. A level sensor (not illustrated) can be arranged in the chamber 9. In order to compensate for the selenium that leaves the chamber 9 with the carrier gas as vapour, said chamber is connected to a container 13 for selenium in the form of a funnel via pipelines 14 (FIG. 1). The selenium is stored in the solid state in the form of small balls at room temperature in the container 13 and in this state is supplied to the chamber 9 and evaporated there.

In order to avoid the situation in which, when the chamber 9 is filled, vaporous selenium escapes from it via the pipelines 14 and the container 13, a metering and lock device 16 is situated between the container 13 and the chamber 9 (FIG. 1).

The metering and lock device 16, not illustrated in greater detail, comprises a cylindrical housing with a centrally mounted rotary part. The housing is provided with two holes, to be precise one at the top side and one at the underside in each case on the same pitch circle diameter, but offset by 180°. The rotary part is likewise provided with two holes on the same pitch circle diameter, offset by 180°. If the upper hole in the housing is in alignment above one of the holes in the rotary part, then selenium balls can fall from the container 13 into the holes. If the rotary part is subsequently rotated through 180°, the selenium balls can pass from the hole in the rotary part through the lower hole in the housing through the pipelines 14 into the chamber 9. At the same time, the respective other hole in the rotary part is filled again with selenium balls from the container.

There is additionally situated between the metering and lock device 14 and the chamber 9 a valve 16 comprising a ball valve with a complete opening, which is briefly opened only during the metering of the selenium balls in the metering and lock device 15.

In this way, firstly a precise metering that meets requirements is made possible, but secondly it is also ensured that no vaporous selenium can escape.

In order to achieve a homogeneous distribution of the selenium vapour/carrier gas mixture over the width of the slot 8, a plurality of constrictions and extensions are arranged one behind another in the vapour deposition head 11 along the channel 10, such that the selenium vapour, on its way to the slot 8, can be accumulated and subsequently expand again in an expansion zone. This process is repeated a number of times, such that the selenium vapour is distributed over the desired width and then leaves the vapour deposition head 11 through the slot 8 into the transport channel 6.

It goes without saying that the vapour deposition head 11 must be constantly kept above the evaporation temperature of the selenium by means of the heating system 12.

Instead of the feed device in the form of one or more slots 8, it is also possible to arrange in the oxygen-free space in the transport channel 6 between the two locks 4, 5 one or more coating heads (not illustrated) for chalcogens, e.g. selenium, in the transport channel above the substrates 3.

Said coating heads can be configured in a manner similar to spray heads of a shower. The coating head is therefore a planar element having numerous outflow openings for the vaporous selenium.

As an alternative, the coating head can also be embodied like a simple tube containing a plurality of openings through which the chalcogens can emerge.

Both the sources for the chalcogens, i.e. the chamber 9, and the supply lines to the slot 8 in the vapour deposition head 11 have to be at a temperature above the evaporation temperature of the chalcogens, such that the vaporous chalcogens can emerge from the slot 8 and the vapour can be deposited on the substrates 3. This prevents chalcogens from depositing unintentionally and clogging the slot 8.

The substrates 3 run past below the slot or slots 8 on a transport device 2 with rollers, on a conveyor belt or on a gas cushion. The substrates 3 are either cooled or at room temperature around 20° C. or are heated. The substrates 3 are preferably at room temperature. The substrates 3 can be heated by the vapour deposition head. This heating is unimportant for the process. The substrates 3, after coating with the chalcogens, are fed to a heat treatment furnace (not illustrated), in which the metallic layers are then converted as required into compound semiconductor layers in a manner mediated by chalcogens.

Excess chalcogen/carrier gas mixture is removed from the process chamber 1 by means of an extraction and disposal device 17 and solid chalcogen, e.g. selenium, obtained in the process is collected in a collecting container 18. For this purpose, the vaporous chalcogen/carrier gas mixture is conducted through a so-called chalcogen trap 19, in which the chalcogen undergoes transition to the solid state of matter and from there is conducted into the collecting container 18.

The apparatus according to the invention and the method not only make it possible to deposit the above-mentioned chalcogens on any desired substrates, e.g. on glass or silicon substrates, but they can also be used without any problems for any other coating purposes and also other evaporable substances.

### LIST OF REFERENCE SYMBOLS

1 Process chamber

2 Transport device

3 Large-area substrate

4 Inlet-side lock

5 Outlet-side lock

6 Transport channel

7 Feed device for chalcogens

8 Slot

9 Chamber

10 Channel

11 Vapour deposition head

12 Heating device

13 Container

14 Pipeline

15 Metering and lock device

16 Valve

17 Extraction and disposal device

18 Collecting container

19 Chalcogen trap

1. Coating method for providing chalcogens in the form of thin layers on substrates, comprising:
forming an inlet- and outlet-side gas curtain for an oxygen-tight closure of a transport channel in a vapour deposition head of a process chamber,
introducing an inert gas into the transport channel for displacing atmospheric oxygen,
introducing one or more substrates to be coated, said substrates being temperature-regulated to a predetermined temperature, into the transport channel of the process chamber,
introducing a chalcogen vapour/carrier gas mixture from a source into the transport channel at the vapour deposition head above the substrates and forming a selenium layer on the substrates by means of PVD at a predetermined pressure, and
removing the substrates after a predetermined process time has elapsed.

2. Method according to claim 1, wherein an atmospheric pressure is set in the transport channel.

3. Method according to claim 1, wherein atmospheric pressure is set in the transport channel.

4. Method according to claim 1, wherein the substrates are moved relative to the vapour deposition head during coating.

5. Method according to claim 4, wherein the substrates are moved at a constant speed.

6. Method according to claim 1, wherein the substrates are temperature-regulated to a temperature of below 200° C. prior to being transported into the transport channel of the process chamber.

7. Method according to claim 6, wherein the substrates are temperature-regulated to a temperature of 20° C. to 50° C.

8. Method according to claim 6, wherein the substrates are temperature-regulated to room temperature.

9. Coating method according to claim 1, wherein the selenium layer is formed with exclusion of oxygen by gas curtain formed on the inlet and outlet sides of the transport channel in the process chamber.

10. Coating method according to claim 9, wherein the gas curtain is formed with an inert gas.

11. Coating method according to claim 10, wherein the inert gas comprises a noble gas.

12. Coating method according to claim 11, wherein the noble gas comprises argon.

13. Coating method according to claim 1, wherein the chalcogen vapour/carrier gas mixture is conducted from the vapour deposition head directly onto a surface of the substrates.

14. Apparatus for carrying out the method according to claim 1, comprising a process chamber is provided with a transport channel for a transport device for flat substrates, the transport channel is provided with oxygen-tight gas curtains composed of inert gas or a noble gas on the-inlet and outlet sides, the transport channel is adapted to be filled with a carrier gas in the process chamber between the gas curtains, and in that a vapour deposition head is arranged directly above the substrates in the transport channel, said vapour deposition head being connected to a feed device for the chalcogen vapour/carrier gas mixture.

15. Apparatus according to claim 14, wherein the vapour deposition head is provided with a slot arranged transversely with respect to a transport direction of the substrates and is directed at the substrates in the transport channel for feeding the chalcogen vapour/carrier gas mixture.

16. Apparatus according to claim 15, wherein a plurality of constrictions followed by expansion zones are arranged one behind another in the vapour deposition head in a channel between an evaporation chamber and the slot over an entire width of the slot, such that the selenium vapour/carrier gas mixture is multiply compressed and expanded on its way to the slot.

17. Apparatus according to claim 14, wherein the vapour deposition head is configured as a spray head and provided with a multiplicity of outflow openings.

18. Apparatus according to claim 14, further comprising a heater for heating the vapour deposition head and the evaporation chamber including associated connecting elements heated.

19. Apparatus according to claim 14, wherein all components with which chalcogen vapour or the chalcogen vapour/carrier gas mixture can make contact are composed of a material resistant to said mixture.

20. Apparatus according to claim 14, further comprising a pressure setter for setting the pressure in the process chamber and the transport channel between fine vacuum and atmospheric pressure.

21. Apparatus according to claim 14, further comprising a temperature regulator for regulating temperature of the substrates to temperatures of between −50° C. and +100° C. on a transport device.

22. Apparatus according to claim 21, wherein the substrates are temperature-regulated to room temperature.

23. Apparatus according to claim 19, wherein the material comprises graphite.

24. Method according to claim 1, wherein the substrates comprise planar substrates prepared with precursor layers and composed of any desired material.

25. Method according to claim 24, wherein the substrates are composed of float glass.
